(19) United States
(12) Patent Application Publication
(10) Pub. No.: US 2026/0025007 A1
(43) Pub. Date: Jan. 22, 2026

(54) SECONDARY BATTERY CHARGING SYSTEM HAVING DATA BACKUP FUNCTION AND DATA BACKUP METHOD

(71) Applicant: SAMSUNG SDI CO., LTD., Yongin-si (KR)

(72) Inventor: Daehee Moon, Yongin-si (KR)

(21) Appl. No.: 19/272,848

(22) Filed: Jul. 17, 2025

(30) Foreign Application Priority Data
Jul. 19, 2024 (KR) 10-2024-0095862

(51) Int. Cl. H02J 7/00; B60L 58/10; G01R 31/367; G01R 31/371; H01M 10/42; H01M 10/48

(52) U.S. Cl. CPC H02J 7/00036; B60L 58/10; G01R 31/367; G01R 31/371; H01M 10/425; H01M 10/486; H02J 7/0047; H01M 2010/4271; H01M 2010/4278

(57) ABSTRACT

A secondary battery charging system includes: an application including a battery and a battery management system (BMS); and a charger configured to supply charging power to the battery and to communicate with the application. Data related to at least one of the battery and the application is transmitted to the charger.

### CROSS-REFERENCE TO RELATED APPLICATION

The present application claims priority to and the benefit of Korean Patent Application No. 10-2024-0095862, filed on Jul. 19, 2024, in the Korean Intellectual Property Office, the entire disclosure of which is incorporated herein by reference.

### BACKGROUND

### 1. Field

Aspects of embodiments of the present disclosure relate to a secondary battery charging system having a data backup function and a data backup method.

### 2. Description of the Related Art

Different from primary batteries that are not designed to be charged, secondary batteries are batteries that are designed to be charged and discharged. Low-capacity secondary batteries are used in small portable electronic devices, such as smartphones, feature phones, laptop computers, digital cameras, and camcorders, and high-capacity secondary batteries are widely used as power sources for driving motors and power storage batteries in hybrid vehicles, electric vehicles, and the like. A secondary battery generally includes an electrode assembly including a positive electrode and a negative electrode, a case accommodating the same, and an electrode terminal connected to the electrode assembly.

Secondary batteries are often applied to applications (e.g., devices) in the form of battery modules or packs, and a battery management system (BMS) may be included therewith. The BMS may measure the voltage, current, temperature, or the like of batteries included in applications, such as electric vehicles or energy storage systems (ESSs) to control the batteries to provide optimal performance and may store related data in the event of failures or fires of a battery or application.

However, when a major fire occurs in a battery module/pack or application, a BMS often entirely burns down, and in such cases, it is not easy or even possible to analyze and estimate the cause of a fire.

The above information disclosed in this Background section is for enhancement of understanding of the background of the present disclosure, and therefore, it may contain information that does not constitute a related (or prior) art.

### SUMMARY

Embodiments of the present disclosure allow data of an application, through which a state of a battery may be estimated during charging of the battery, to be always (or constantly) updated to a charger or charging system rather than a battery management system (BMS) as backup data, thereby allowing the cause of an event to be easily analyzed and estimated when the event occurs in the battery module/pack or application.

According to an embodiment of the present disclosure, a secondary battery charging system includes an application, which includes a battery and a BMS, and a charger configured to supply charging power to the battery of the application and to communicate with the application. Data related to at least one of the battery and the application is transmitted to the charger.

According to another embodiment of the present disclosure, a data backup method performed in a secondary battery charging system is provided. The data backup method includes, acquiring, by a BMS, battery state information, acquiring, by the BMS, event-related information in at least one of a battery and an application, and transmitting the acquired battery state information and the event-related information to a charger.

Aspects and features of the present disclosure are not limited to those described above, and other aspects and features not specifically mentioned herein will be clearly understood by those skilled in the art from the description of the present disclosure below.

### BRIEF DESCRIPTION OF THE DRAWINGS

The following drawings attached to the present specification illustrate embodiments of the present disclosure and further describe aspects and features of the present disclosure together with the detailed description of the present disclosure. Thus, the present disclosure should not be construed as being limited to the drawings, in which:

FIG. 1 schematically illustrates a pouch-type secondary battery;

FIG. 2 is a cross-sectional view of a cylindrical secondary battery;

FIG. 3A is a top perspective view of an exterior of a prismatic secondary battery;

FIG. 3B is a cross-sectional view taken along the line I-I′ in FIG. 3A;

FIG. 4 is a view of a battery module in which secondary batteries are arranged;

FIG. 5 is a view of a battery pack including the battery modules illustrated in FIG. 4;

FIG. 6 is a schematic illustration of a vehicle including the battery pack shown in FIG. 5;

FIG. 7 is a block diagram describing a secondary battery charging system having a data backup function according to an embodiment of the present disclosure;

FIG. 8 is a block diagram describing a secondary battery charging system having a data backup function according to another embodiment of the present disclosure;

FIG. 9 is a block diagram describing a battery management system (BMS) configured to manage a battery of an application;

FIG. 10A is a block diagram describing a data acquisition unit of a data backup system according to an embodiment of the present disclosure;

FIG. 10B is a block diagram describing a data acquisition unit of a data backup system according to another embodiment of the present disclosure;

FIG. 11 is a flowchart describing a process of executing a task for a data backup system to acquire data according to an embodiment of the present disclosure;

FIG. 12 is a block diagram describing a BMS according to another embodiment of the present disclosure; and

FIG. 13 is a flowchart describing a process in which a BMS executes the highest priority notification task when an event occurs.

### DETAILED DESCRIPTION

Hereinafter, embodiments of the present disclosure will be described, in detail, with reference to the accompanying drawings. The terms or words used in the present specification and claims should not be narrowly interpreted according to their general or dictionary meanings but should be interpreted as having meanings and concepts that are consistent with the technical idea of the present disclosure on the basis of the principle that an inventor can be his/her own lexicographer to appropriately define concepts of terms to describe his/her invention in the best way.

The embodiments described in this specification and the configurations shown in the drawings are only some embodiments of the present disclosure and do not represent all of the aspects, features, and embodiments of the present disclosure. Accordingly, it should be understood that there may be various equivalents and modifications that can replace or modify one or more embodiments or features therein described herein at the time of filing this application.

It will be understood that if an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, if a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” if describing embodiments of the present disclosure relates to “one or more embodiments of the present disclosure.” Expressions, such as “at least one of” and “any one of,” if preceding a list of elements, modify the entire list of elements and do not modify the individual elements of the list. When phrases such as “at least one of A, B and C, “at least one of A, B or C,” “at least one selected from a group of A, B and C,” or “at least one selected from among A, B and C” are used to designate a list of elements A, B and C, the phrase may refer to any and all suitable combinations or a subset of A, B and C, such as A, B, C, A and B, A and C, B and C, or A and B and C. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” if used in this specification, specify the presence of stated features, integers, steps, operations, elements, and/or components but do not preclude the presence or addition of one or more other features, integers, steps, operations, elements, components, and/or groups thereof.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112 (a) and 35 U.S.C. § 132 (a).

References to two compared elements, features, etc. as being “the same” may mean that they are “substantially the same.” Thus, the phrase “substantially the same” may include a case having a deviation that is considered low in the art, for example, a deviation of about 5% or less. In addition, if a certain parameter is referred to as being uniform in a given region, it may mean that it is uniform in terms of an average.

Throughout the specification, unless otherwise stated, each element may be singular or plural.

Arranging an arbitrary element “above (or below)” or “on (under)” another element may mean that the arbitrary element may contact the upper (or lower) surface of the element, and another element may also be interposed between the element and the arbitrary element located on (or under) the element.

In addition, it will be understood that if a component is referred to as being “linked,” “coupled,” or “connected” to another component, the elements may be directly “coupled,” “linked” or “connected” to each other, or another component may be “interposed” between the components.”

Throughout the specification, if “A and/or B” is stated, it means A, B or A and B, unless otherwise stated. That is, “and/or” includes any or all combinations of a plurality of items enumerated. When “C to D” is stated, it means C or more and D or less, unless otherwise specified.

The terminology used herein is for the purpose of describing embodiments of the present disclosure and is not intended to limit the present disclosure.

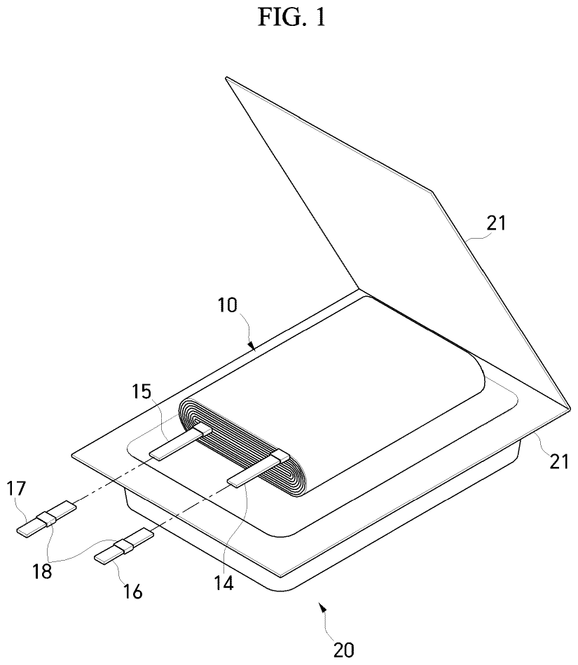

FIG. 1 schematically illustrates a pouch-type secondary battery.

The pouch-type secondary battery includes an electrode assembly 10 and a pouch 20 that accommodates the electrode assembly 10.

The first electrode tab 14 and the second electrode tab 15 of the electrode assembly 10 may be electrically connected to respective external first and second terminal leads 16 and 17 by welding. Each of the first terminal lead 16 and the second terminal lead 17 may be attached with (e.g., partially covered by) a tab film 18 for insulation from the pouch 20.

The pouch 20 may be sealed by having sealing parts 21 at the edges thereof come into contact with each other while accommodating the electrode assembly 10 therein, and the sealing may be achieved with the tab film 18 interposed between the sealing parts 21. The sealing parts 21 of the pouch 20 may each be made of a thermal fusion material that generally has weak adhesion to metal. Thus, the sealing parts 21 of the pouch 20 may be fused to the pouch 20 by interposing the thin film 18 between the sealing parts 21.

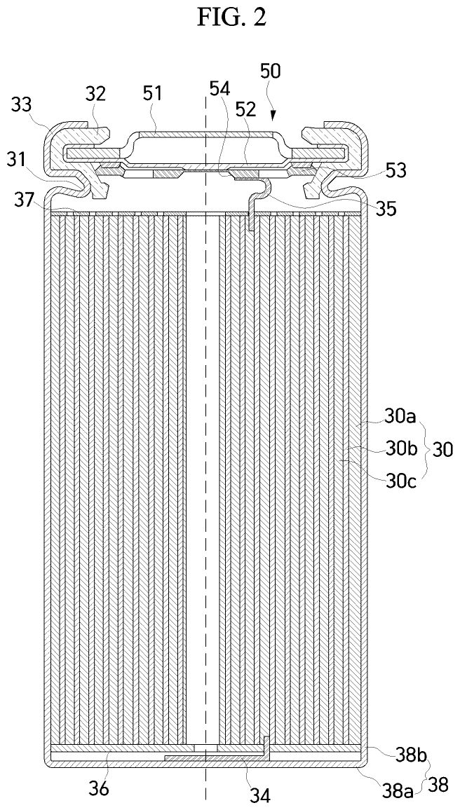

FIG. 2 illustrates a cylindrical secondary battery. The cylindrical secondary battery includes an electrode assembly 30, a case (e.g., a can) 38 accommodating the electrode assembly 30 and an electrolyte therein, a cap assembly 50 coupled at an opening in the case 38 to seal the case 38, and an insulating plate 37 positioned between the electrode assembly 30 and the cap assembly 50 inside the case 38.

The electrode assembly 30 may include a separator 30b and a first electrode 30c and a second electrode 30a positioned with the separator 30b interposed therebetween and may be wound together in a jelly-roll shape.

The first electrode 30c includes a first substrate and a first active material layer on the first substrate. A first lead tab 35 may extend outwardly from a first uncoated portion of the first substrate at where the first active material layer is not located (e.g., is not formed), and the first lead tab 35 may be electrically connected to the cap assembly 50.

The second electrode 30a includes a second substrate and a second active material layer on the second substrate. A second lead tab 34 may extend outwardly from a second uncoated portion of the second substrate at where the second active material layer is not located (e.g., is not formed), and the second lead tab 34 may be electrically connected to the case 38. The first lead tab 35 and the second lead tab 34 may extend in opposite directions.

The first electrode 30c may act as a positive electrode. In such an embodiment, the first substrate may be made of, for example, an aluminum foil, and the first active material layer may include, for example, a transition metal oxide. The second electrode 30a may act as a negative electrode. In such an embodiment, the second substrate may be made of, for example, a copper foil or a nickel foil, and the second active material layer may include graphite, for example.

The separator 30b prevents a short circuit between the first electrode 30c and the second electrode 30a while allowing movement of lithium ions therebetween. The separator 30b may be made of, for example, a polyethylene film, a polypropylene film, a polyethylene-polypropylene film, or the like.

The case 38 accommodates the electrode assembly 30 and, together with the cap assembly 50, forms the external appearance of the secondary battery. The case 38 may have a substantially cylindrical body portion 38b and a bottom portion 38a connected to (e.g., extending from) one side (e.g., to one end) of the body portion 38b. A beading part 31 (e.g., a bead) deformed inwardly may be formed in the body portion 38b, and a crimping part 33 (e.g., a crimp) bent inwardly may be formed at an open end of the body portion 38b.

The beading part 31 can reduce or prevent movement of the electrode assembly 30 inside the case 38 and can facilitate seating of a gasket 32 and the cap assembly 50. The crimping part 33 may firmly fix the cap assembly 50 by pressing the edge of the case 38 against the gasket 32. The case 38 may be formed of iron plated with nickel, for example.

The cap assembly 50 may be fixed to the inside of the crimping part by a gasket 32 to seal the case 38. The cap assembly 50 may include a cap up 51, a safety vent 52, a cap down 53, an insulating member, and a sub plate 54 but is not limited thereto and may be modified in various ways.

The cap up 51 may be positioned at the uppermost part of the cap assembly 50. The cap up 51 may include a terminal part that protrudes upwardly to be connected to an external circuit, and an outlet (e.g., an opening) for discharging gas may be arranged around the terminal part.

The safety vent 52 may be located under the cap up 51. The safety vent 52 may include a protrusion part that protrudes convexly downwardly and is connected to the sub plate 54, and at least one notch may be formed in the safety vent 52 around the protrusion part.

When gas is generated due to overcharging or abnormal operation of the secondary battery, the protrusion part deforms upwardly due to the pressure and separates from the sub plate 54 while the safety vent 52 is cut (e.g., bursts or tears) along the notch. The cut safety vent 52 may prevent the secondary battery from exploding by allowing excess gas to be discharged to the outside.

The cap down 53 may be below the safety vent 52. The cap down 53 may have a first opening for exposing the protrusion part of the safety vent 52 and a second opening for gas discharge. The insulating member may be positioned between the safety vent 52 and the cap down 53 to insulate the safety vent 52 and the cap down 53.

The sub plate 54 may be under the cap down 53. The sub plate 54 may be fixed to a lower surface of the cap down 53 to block the first opening of the cap down 53, and the protrusion part of the safety vent 52 may be fixed to the sub plate 54. The first lead tab 35, which is drawn out from the electrode assembly 30, may be fixed to the sub plate 54. Accordingly, the cap up 51, the safety vent 52, the cap down 53, and the sub plate 54 may be electrically connected to the first electrode 30c of the electrode assembly 30.

The insulating plate 37 may be positioned to be in contact with the electrode assembly 30 below the beading part 31. The insulating plate 37 may have a tab opening through which the first lead tab 35 is drawn out. The cap assembly 50, which is electrically connected to the first electrode 30c by the first lead tab 35, may face the electrode assembly 30 with an insulating plate 37 interposed therebetween and may maintain a state of being insulated (e.g., electrically insulated) from the electrode assembly 30 by the insulating plate 37. Another insulating plate 36 may be included for insulation between the electrode assembly 30 and the bottom portion 38a of the case 38.

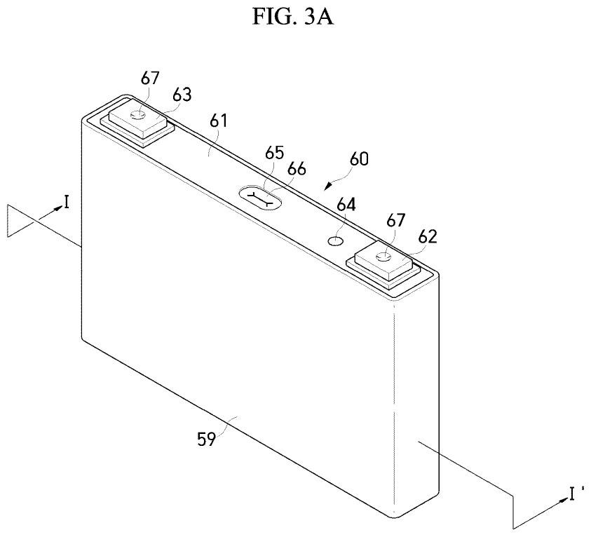

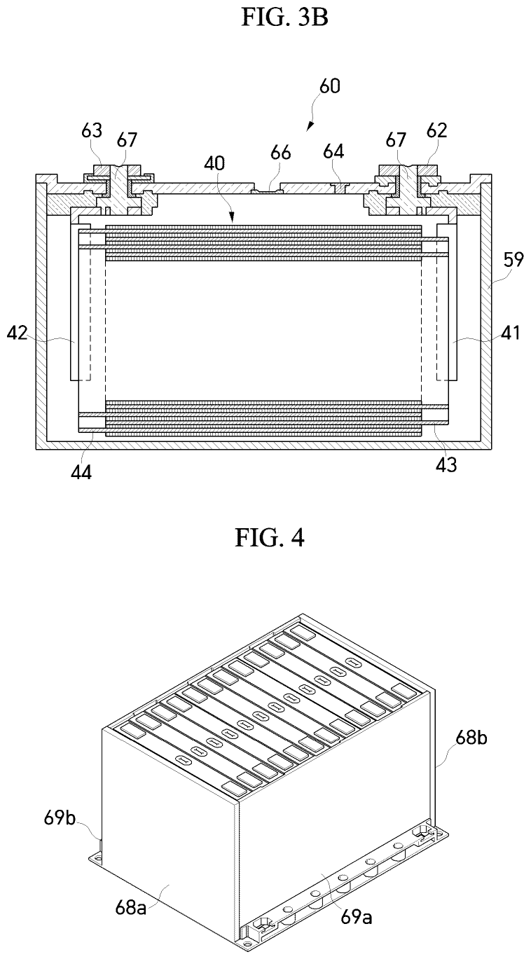

FIG. 3A is a top perspective view of a prismatic secondary battery.

A case 59 defines an overall appearance of the prismatic secondary battery and may be made of a conductive metal, such as aluminum, aluminum alloy, or nickel-plated steel. In addition, the case 59 may provide (or may form) a space for accommodating an electrode assembly therein.

A cap assembly 60 may include a cap plate 61 that covers the opening in the case 59. In some embodiments, the case 59 and the cap plate 61 may be made of a conductive material. In the illustrated embodiment, a first terminal 62 and a second terminal 63 may be electrically connected to respective positive and negative (or negative and positive) electrodes inside the case 59 and may be installed to protrude outwardly through the cap plate 61.

The cap plate 61 may be equipped with (or may have) an electrolyte injection port 64 formed to install (or to receive) a sealing plug (e.g., a seal pin), and a vent 66 formed with a notch 65. The vent 66 is for discharging excess gas generated inside the secondary battery.

FIG. 3B is a cross-sectional view taken along the line I-I′ in FIG. 3A.

As shown in FIG. 3B, the prismatic secondary battery may include an electrode assembly 40, a first current collector 41, the first terminal 62, a second current collector 42, the second terminal 63, the case 59, and the cap assembly 60.

An electrode assembly 40 may be formed by winding or stacking a stack of a first electrode plate, a separator, and a second electrode plate, which are each formed as thin plates or films. When the electrode assembly 40 is a wound stack, a winding axis may be parallel to the longitudinal direction of the case 59. In some other embodiments, the electrode assembly 40 is a stack type rather than a winding type, and the shape of the electrode assembly 40 is not limited in the present disclosure. In addition, the electrode assembly 40 may be a Z-stack electrode assembly in which a positive electrode plate and a negative electrode plate are inserted into both sides (e.g., opposite sides) of a separator, which is then bent (or folded) into a Z-stack. In addition, one or more electrode assemblies 40 may be stacked such that long sides of the electrode assemblies 40 are adjacent to each other and accommodated in the case 59, and the number of electrode assemblies 40 in the case 59 is not limited in the present disclosure. The first electrode plate of the electrode assembly 40 may act as a negative electrode, and the second electrode plate may act as a positive electrode. Of course, the reverse is also possible.

The first electrode plate may be formed by applying a first electrode active material, such as graphite, carbon, or the like, to a first electrode current collector formed of a metal foil, such as copper, a copper alloy, nickel, a nickel alloy, or the like. The first electrode plate may include a first electrode tab 43 (e.g., a first uncoated portion) that is a region to which the first electrode active material is not applied. The first electrode tab 43 may act as a current flow path between the first electrode plate and the first current collector 41. In some embodiments, when the first electrode plate is manufactured, the first electrode tab 43 is formed by being cut in advance to protrude to one side of the electrode assembly 40, or the first electrode tab 43 protrudes to one side of the electrode assembly 40 more than (e.g., farther than or beyond) the separator without being separately cut.

The second electrode plate may be formed by applying a second electrode active material, such as a transition metal oxide, on a second electrode current collector formed of a metal foil, such as aluminum or an aluminum alloy. The second electrode plate may include a second electrode tab 44 (e.g., a second uncoated portion) that is a region to which the second electrode active material is not applied. The second electrode tab 44 may act as a current flow path between the second electrode plate and the second current collector 42. In some embodiments, the second electrode tab 44 may be formed by being cut in advance to protrude to the other side (e.g., the opposite side) of the electrode assembly when the second electrode plate is manufactured, or the second electrode plate may protrude to the other side of the electrode assembly more than (e.g., farther than or beyond) the separator without being separately cut.

The separator prevents or substantially reduces instances of a short circuit between the first electrode and the second electrode while allowing movement of lithium ions therebetween. The separator may be made of, for example, a polyethylene film, a polypropylene film, a polyethylene-polypropylene film, or the like.

In some embodiments, the electrode assembly 40 is accommodated in the case 59 along with an electrolyte.

In the electrode assembly 40, the first current collector 41 and the second current collector 42 may be welded and connected to the first electrode tab 43 extending from the first electrode plate and the second electrode tab 44 extending from the second electrode plate, respectively. In embodiments in which the first electrode tab 43 and the second electrode tab 44 are located at the top of the electrode assembly 40, the first and second current collectors are located at the top of the electrode assembly 40.

As illustrated in FIG. 3B, the first current collector 41 and the second current collector 42 are connected to the first terminal 62 and the second terminal 63 through connection members 67, respectively. In some embodiments, the connection members 67 may each have an outer peripheral surface that is threaded and may be fastened to the first terminal 62 and the second terminal 63 by screwing. However, the present disclosure is not limited thereto. For example, the connection members 67 may also be coupled to the first terminal 62 and the second terminal 63 by riveting or welding.

FIG. 4 is a perspective view of a secondary battery module in which secondary batteries are arranged according to embodiments of the present disclosure. With the increase in secondary battery capacity for driving electric vehicles or the like, a secondary battery module may be manufactured by arranging a plurality of secondary battery cells transversely and/or longitudinally and connecting them together. The plurality of secondary batteries may be arranged in a space defined by a pair of facing end plates 68a and 68b and a pair of facing side plates 69a and 69b. The secondary batteries may be arranged in an arrangement (e.g., direction and/or connection configuration) and number to obtain desired voltage and current specifications.

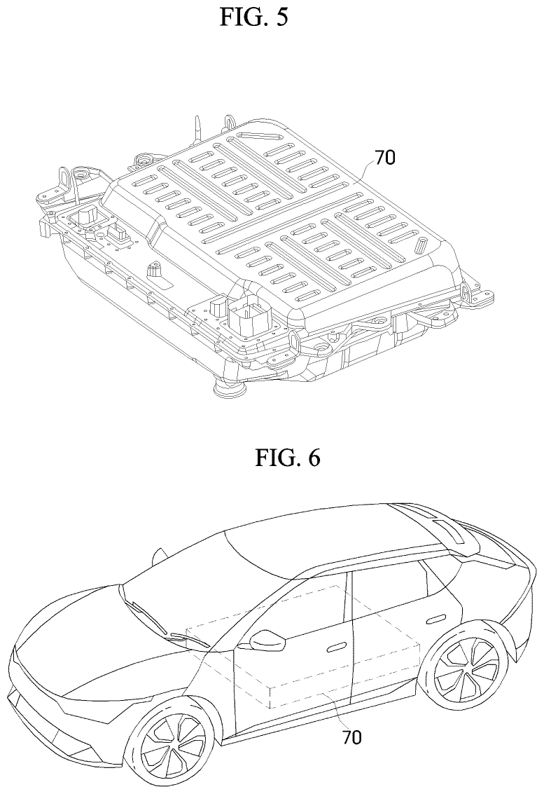

FIG. 5 is a perspective view of a battery pack 70 according to embodiments of the present disclosure. Referring to FIG. 5, the battery pack 70 may include an assembly to which individual batteries are electrically connected and a pack housing accommodating the same. In the drawings, for convenience of illustration, components such as a bus bar, a cooling unit, external terminals for electrically connecting batteries, etc., are not shown.

The battery pack 70 may be mounted on (or in) a vehicle. The vehicle may be, for example, an electric vehicle, a hybrid vehicle, or a plug-in hybrid vehicle. The vehicle may be a four-wheeled vehicle or a two-wheeled vehicle but is not limited thereto. FIG. 6 shows a vehicle that includes the battery pack 70 shown in FIG. 5 on the lower body thereof. The vehicle may operate by (e.g., may be powered by) receiving power from the battery pack 70.

The secondary battery pack may include a battery and a battery management system (BMS) for managing the battery. The BMS measures sensors, determines (e.g., determines in advance) the voltage (V), current (I), and temperature (T) of batteries installed in electric vehicles or ESS, and controls the batteries so that they can perform optimally.

The BMS may include a detection device, a balancing device, and a control device. The battery module may include a plurality of cells connected to each other in series and/or parallel. The battery modules may be connected to each other in series and/or in parallel.

The detection device may detect a state of a battery (e.g., voltage, current, temperature, etc.) and may output state information indicating the state of the battery. The detection device may detect the voltage of each cell constituting the battery or of each battery module. The detection device may detect current flowing through each battery module constituting the battery module or the battery pack. The detection device may also detect the temperature of a cell and/or module on at least one point of the battery and/or an ambient temperature.

The balancing device may perform a balancing operation of a battery module and/or cells constituting the battery module. The control device may receive state information (e.g., voltage, current, temperature, etc.) of the battery module from the detection device. The control device may monitor and calculate the state of the battery module (e.g., voltage, current, temperature, state of charge (SOC), life span (state of health (SOH)), etc.) based on (or according to) the state information received from the detection device. In addition, based on (or according to) the monitored state information, the control device may perform a control function (e.g., temperature control, balancing control, charge/discharge control, etc.) and a protection function (e.g., over-discharge, over-charge, over-current protection, short circuit, fire extinguishing function, etc.). In addition, the control device may perform a wired or wireless communication function with an external device of the battery pack (e.g., a higher level controller or vehicle, charger, power conversion system, etc.).

The control device may control charging/discharging operation and protection operation of the battery. To this end, the control device may include a charge/discharge control unit, a balancing control unit, and/or a protection unit.

The BMS is a system that monitors the battery state, performs diagnosis and control, communication, and protection functions, and may calculate the charge/discharge state, calculate battery life or state of health (SOH), cut off, as necessary, battery power (e.g., relay control), control thermal management (e.g., cooling, heating, etc.), perform a high-voltage interlock function, and/or may detect and/or calculate insulation and short circuit conditions.

A relay may be a mechanical contactor that is turned on and off by the magnetic force of a coil or a semiconductor switch, such as a metal oxide semiconductor field effect transistor (MOSFET).

The relay control has a function of cutting off the power supply from the battery if (or when) a problem occurs in the vehicle and the battery system and may include one or more relays and pre-charge relays at the positive terminal and the negative terminal, respectively.

In the pre-charge control, there is a risk of inrush current occurring in the high-voltage capacitor on the input side of the inverter when the battery load is connected. Thus, to prevent or mitigate inrush current when starting a vehicle, the pre-charge relay may be operated before connecting the main relay and the pre-charge resistor may be connected.

The high-voltage interlock is a circuit that uses a small signal to detect whether or not all high-voltage parts of the entire vehicle system are connected and may forcibly open a relay if (or when) an opening occurs at even one location on the entire loop.

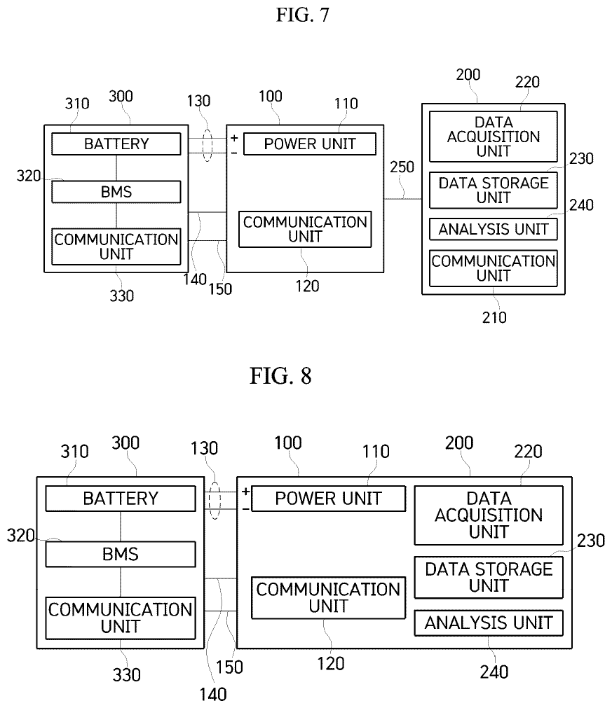

FIG. 7 is a block diagram describing a secondary battery charging system having a data backup function according to an embodiment of the present disclosure.

Generally, a charger 100 is connected to an application 300. The charger 100 may supply charging power to the application 300 through a power line 130 and may communicate with the application 300 through a communication line 140. A state in which the charger 100 is connected to the application 300 may be checked (or determined) through a charger connection checking line 150. The charger 100 may also communicate with a data backup system 200 through a communication line 250.

The application 300 may include a battery 310, a battery management system (BMS) 320, and a communication unit 330 for communication with the charger 100. The charger 100 may include a power unit 110 that generates charging power and is supplied to the application 300, and a communication unit 120 for communication with the application 300. The data backup system 200 may include a communication unit 210 for communication with the charger 100, a data acquisition unit 220 for receiving data of (e.g., from or regarding) the application 300 through the communication unit 120, and a data storage unit 230 for storing acquired data.

Here, data may include “battery state information” indicating a state of a battery and “event information” used to estimate the battery state information as well as a position (e.g., location) and a time at which an event occurs. The battery state information may include a voltage, a current, a temperature, a SoX (e.g., state of charge (SOC), state of energy (SOE), state of health (SOH), etc.)), and a lifetime (state of health (SOH)) of a battery cell or pack (hereinafter collectively referred to as a battery). The battery state information may include information (e.g., first state information) that may be detected from a battery by a sensor and information (e.g., second state information) that may be obtained through calculation. The former may be a voltage, a current, a temperature, or the like of the battery, and the latter may be a SoX. The event information may be an identification code or ID of the application 300, a model name or ID of the battery module/pack, an event code, such as a fire, and/or an event occurrence time.

In some embodiments, the data backup system 200 may include an analysis unit 240 that analyzes data stored in the data storage unit 230 and estimates the cause of an event that has occurred in the application 300. For example, when the BMS 320 of the application 300 is entirely burned down due to a fire, the cause of the fire may be estimated by analyzing battery state information, such as a voltage, a current, and a temperature of a battery cell and/or pack stored in the data storage unit 230 at or near the time of the fire.

Although the communication unit 330 of the application 300 is shown in FIG. 7 as a separate block, this represents a functional distinction, and actually, the communication unit 330 may be included in the BMS 320 or other elements. The communication unit 330 of the application 300 and the communication unit 120 of the charger 100 may communicate with each other in a wired communication or wireless communication manner. In addition, the communication unit 120 of the charger 100 and the communication unit 210 of the data backup system 200 may communicate with each other in a wired communication or wireless communication manner.

FIG. 8 is a block diagram describing a secondary battery charging system having a data backup function according to other embodiments of the present disclosure.

Generally, a charger 100 integrated with a data backup system 200 is connected to an application 300. In the illustrated embodiment, the charger 100 may include a power unit 110 that generates charging power to be supplied to the application 300, a communication unit 120 for communication with the application 300, a data acquisition unit 220 that receives data from the application 300 through the 1 communication unit 120, and a data storage unit 230 that stores acquired data. In other embodiments, the charger 100 may include an analysis unit 240 that analyzes data stored in the data storage unit 230 and estimates the cause of an event that has occurred in the application 300.

The embodiment shown in FIG. 8 is a configuration that may be constructed when the application 300 and the charger 100 are spaced a distance from each other so that an event, such as a fire occurring in the application 300, is unlikely to affect the charger 100, but the present disclosure is not limited thereto.

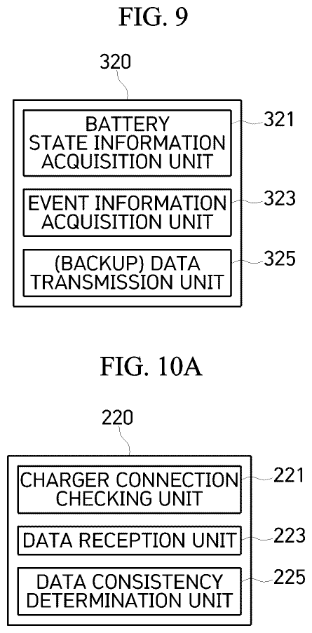

FIG. 9 is a block diagram describing a BMS 320 that manages a battery 310 of an application 300 according to an embodiment. The BMS 320 may include a battery state information acquisition unit 321 that detects first state information of a battery (e.g., a voltage, a current, a temperature, or the like of the battery) from a battery 310 through a sensor and calculates second state information (e.g., a SoX) from information (e.g., from the first state information), an event information acquisition unit 323 that acquires event-related information including at least one of an identification code or ID of the application 300, a model name or ID of a battery module/pack, an event code, such as a fire, and an event occurrence time, and a data transmission unit 325 that transmits the acquired battery state information (e.g., first state information and second state information) and the event-related information to a charger 100 through a communication unit 330. Here, the data transmitted to the charger 100 may be data that will be backed up by being transmitted to a data reception unit 223 of the data backup system 200 as shown in FIG. 7 or a data reception unit 223 in the charger 100 as shown in FIG. 8 and, thus, may be referred to as backup data.

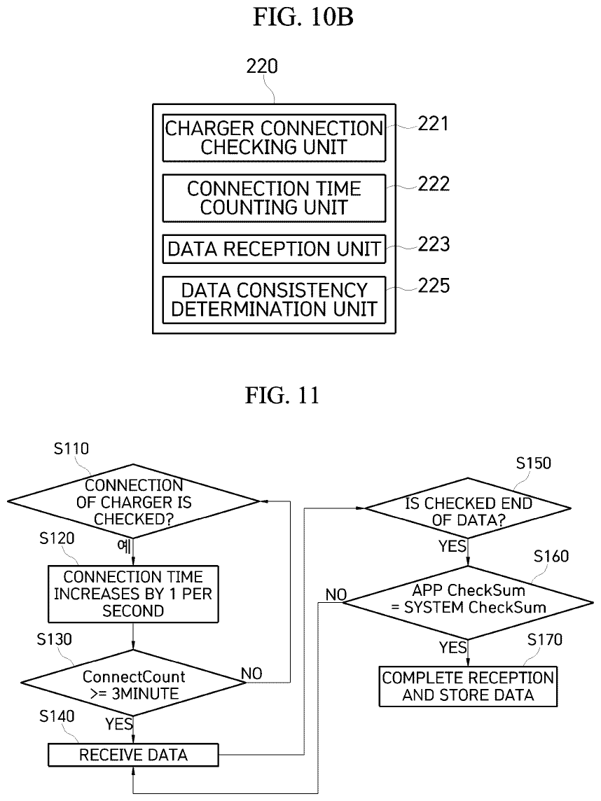

FIG. 10A is a block diagram describing a data acquisition unit 220 according to some embodiments of the present disclosure and illustrates a configuration of the data acquisition unit 220 of the data backup system 200 shown in FIG. 7 or the data acquisition unit 220 of the charger 100 shown in FIG. 8.

In some embodiments, the data acquisition unit 220 of the data backup system 200 may include a charger connection checking unit 221 that performs a task to check (or determine) whether or not a charger 100 is connected to an application 300, a data reception unit 223 that receives data (e.g., backup data) from a data transmission unit 325 of a BMS 320 of the application 300 when the connection of the charger 100 is checked, and a data consistency determination unit 225 that determines and verifies the consistency of the received data.

FIG. 10B is a block diagram describing a data acquisition unit 220 according to other embodiments of the present disclosure.

In some embodiments, the data acquisition unit 220 of a data backup system 200 may include a charger connection checking unit 221 that performs a task to check (or determine) whether or not a charger 100 is connected to an application 300, a connection time counting unit 222 that counts a connection time to determine whether or not a connection state continues for a reference time (e.g., a predetermined time) when it is determined that the charger 100 is connected, a data reception unit 223 that receives data (e.g., backup data) from a data transmission unit 325 of a BMS 320 of the application 300 when it is determined that the connection of the charger 100 continues for the reference time, and a data consistency determination unit 225 that determines and verifies the consistency of the received data.

FIG. 11 is a flowchart describing a process of executing a task for a data backup system 200 to acquire data according to some embodiments of the present disclosure. The process illustrated in FIG. 11 may be executed by the data backup system 200 or a data acquisition unit 220 of a charger 100 (see, e.g., FIG. 10B), but the present disclosure is not limited thereto. However, in the following description, for convenience, a device executing each operation shown in FIG. 11 is the data backup system 200 or the data acquisition unit 220 of the charger 100.

First, the data acquisition unit 220 may check (or determine) whether or not the charger 100 is connected to an application 300 in operation S110.

When the charger 100 is connected to the application 300, the data acquisition unit 220 may measure a connection time of the charger 100 to know whether or not a connection state is continuing in operation S120. For example, a connection time count value (ConnectCount) may increase by 1 per second.

Next, the data acquisition unit 220 may check (or determine) whether or not the connection time count value (ConnectCount) corresponds to a reference time (e.g., 3 minutes) in operation S130, and when the connection time count value (ConnectCount) corresponds to the reference time, data may be received in operation S140.

The data acquisition unit 220 may check (or determine) an end of the received data in operation S150 and may compare a checksum of the application 300 with a checksum of the data backup system 200 to verify data consistency in operation S160. When the data consistency is verified, the data acquisition unit 220 may complete reception and store the received data in a data storage unit 230b in operation S170. Thus, data related to the application 300 and/or a battery 310 may be updated in real time to the charger 100 or the data backup system 200 as backup data.

A basic embodiment of data backup in which the data related to the application 300 and/or the battery 310 is shared between a BMS 320 and the charger 100 or the data backup system 200 has been described.

In some cases, when an event, such as a fire, occurs in the application 300 and/or the battery 310, a failure, such as rapid burning out of the BMS, may occur. To quickly respond in such a case, when it is detected that an event has occurred in the application 300 and/or the battery 310, the BMS 320 may be configured to transmit battery state information and related information to the charger 100 firstly (e.g., by applying an interrupt routine to a processing process of the BMS 320).

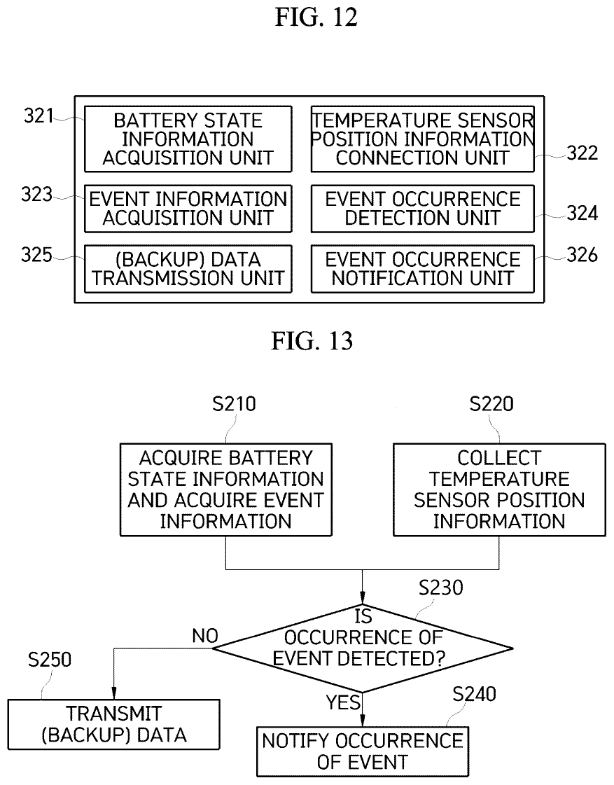

FIG. 12 is a block diagram describing a BMS 320 according to such an embodiment.

In addition to the battery state information acquisition unit 321, the event information acquisition unit 323, and the data transmission unit 325 shown in FIG. 9, the BMS 320 may additionally include a temperature sensor position information collection unit 322, an event occurrence detection unit 324, and an event occurrence notification unit 326.

The temperature sensor position information collection unit 322 may collect a position (e.g., location) of a sensor that measures a temperature of a battery. For example, when a plurality of temperature sensors are installed in an application 300 to which a battery 310 is applied (e.g., when temperature sensors are installed for each pack or module of a container-type energy storage system (ESS)) or when a plurality of temperature sensors are distributed in various positions (e.g., when a plurality of robot cleaners in which temperature sensors are installed are operating or waiting in various positions), position information of each temperature sensor may be collected.

The event occurrence detection unit 324 may detect the occurrence of an event, such as a fire or failure in the battery 310 and/or the application 300. To this end, a tendency or threshold of battery state information is stored for each type of event, and when the battery state information matches the tendency or threshold, the occurrence of the event may be detected. Furthermore, machine learning or an artificial intelligence technique or method may be used to detect the occurrence of an event.

When the event occurrence detection unit 324 detects the occurrence of an event, first, the event occurrence notification unit 326 may notify a charger 100 (or a data backup system 200 through the charger 100) of an event occurrence notification signal that includes the acquired battery state information, event information, and temperature sensor position information of the battery 310 or application 300 in which the event has occurred. The charger 100 or the data backup system 200 may receive the event occurrence notification signal first when an event occurs, thereby enabling quick and immediate event recognition and response. Here, the highest priority 1 notification may be implemented by applying an interrupt routine to a processing process of the BMS 320 (e.g., INTERRUPT=0).

FIG. 13 is a flowchart illustrating a process in which the BMS 320 executes the highest priority notification task when an event described above occurs. The process illustrated in FIG. 13 may be executed by the BMS 320 with the configuration shown in FIG. 12, but the present disclosure is not limited thereto.

The BMS 320 may acquire battery state information and event information in operation S210. Here, the battery state information may be a voltage, a current, a temperature, a SoX (e.g., SOC), a lifetime (SOH), or the like of a battery cell or pack (hereinafter collectively referred to as a battery). Here, the battery state information may include information (e.g., first state information) that may be detected from a battery by a sensor and information (e.g., second state information) that may be obtained through calculation. The former may be a voltage, a current, a temperature, or the like of the battery, and the latter may be a SoX. In addition, the event information may be an identification code or ID of the application 300, a model name or ID of the battery module/pack, an event code such as a fire, or an event occurrence time.

The BMS 320 may collect position (e.g., location) information of a sensor that measures a temperature of the battery in operation S220. For example, when a plurality of temperature sensors are installed in the application 300 to which the battery 310 is applied (e.g., when temperature sensors are installed for each pack or module of a container-type ESS or when a plurality of temperature sensors are distributed in various positions (e.g., when a plurality of robot cleaners in which temperature sensors are installed are operating or waiting in various positions), position information of each temperature sensor may be collected.

Next, the BMS 320 may detect whether or not an event has occurred in operation S230. In this operation, an event, such as a fire or failure occurring in the battery 310 and/or the application 300 is detected. To this end, the BMS 320 may store a tendency or threshold of battery state information for each type of an event, detect the occurrence of a corresponding event when the battery state information matches the tendency or threshold, and further detect the occurrence of the event using machine learning or an artificial intelligence technique.

When the occurrence of the event is detected in operation S230, the BMS 320 may transmit an event occurrence notification signal to the charger 100 or data backup system 200 in operation S240. Such a notification signal may be transmitted first by using an interrupt routine, or the like. In such an embodiment, notified information may include the acquired battery state information, event information, and temperature sensor position (e.g., location) information of the battery 310 or application 300 in which the event has occurred. Accordingly, the charger 100 or data backup system 200 may be notified of the information first when an event occurs, thereby enabling quick and immediate event recognition and response.

In a normal case (e.g., during normal operation) in which the occurrence of an event is not detected in operation S230, the BMS 320 may transmit the acquired battery state information (e.g., first state information and second state information) and event-related information to the charger 100 or data backup system 200 in operation S240. The charger 100 or data backup system 200 may receive (e.g., download) data to update the received data in a storage area (e.g., the data storage unit 230 shown in FIG. 7 or 8).

According to embodiments of the present disclosure, data of an application, through which a state of a battery can be estimated during charging, is updated (e.g., is always updated) to a charger or a separate data backup system to secure key data through which the cause of a battery fire can be estimated, thereby quickly identifying the cause of an event, such as a fire, and preparing for an event that can occur in the future.

The battery management system, the data backup system, the communication unit, and/or any other relevant devices or components (collectively, the devices) according to embodiments of the present disclosure described herein may be implemented utilizing any suitable hardware, firmware (e.g., an application-specific integrated circuit), software, and/or a suitable combination of software, firmware, and hardware. For example, the various components of the devices may be formed on one integrated circuit (IC) chip or on separate IC chips. Further, the various components of the devices may be implemented on a flexible printed circuit film, a tape carrier package (TCP), a printed circuit board (PCB), or formed on a same substrate as the devices. Further, the various components of the devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device or the functionality of a particular computing device may be distributed across one or more other computing devices without departing from the scope of the exemplary embodiments of the present disclosure.

Although the present disclosure has been described above with respect to embodiments thereof, the present disclosure is not limited thereto. Various modifications and variations can be made thereto by those skilled in the art within the spirit of the present disclosure as defined by the appended claims and their equivalents.

What is claimed is:

1. A secondary battery charging system comprising:
an application comprising a battery and a battery management system (BMS); and
a charger configured to supply charging power to the battery and to communicate with the application,
wherein data related to at least one of the battery and the application is transmitted to the charger.

2. The secondary battery charging system as claimed in claim 1, wherein the data comprises battery state information indicating a state of the battery.

3. The secondary battery charging system as claimed in claim 1, wherein the data comprises event information to estimate an occurrence position and time of an event occurring in at least one of the battery and the application.

4. The secondary battery charging system as claimed in claim 1, wherein the charger comprises:
a data acquisition unit configured to receive the data from the application; and
a data storage unit configured to store the received data.

5. The secondary battery charging system as claimed in claim 1, further comprising a data backup system configured to receive the data from the charger and to store the received data,
wherein the data backup system comprises:
a data acquisition unit configured to receive the data of the application from the charger; and
a data storage unit configured to store the received data.

6. The secondary battery charging system as claimed in claim 4, wherein the data acquisition unit comprises:
a charger connection checking unit configured to determine whether or not the charger is connected to the application;
a data reception unit configured to receive data from a data transmission unit of the BMS of the application when the charger connection checking unit determines that the charger is connected; and
a data consistency determination unit configured to determine and verify consistency of the received data.

7. The secondary battery charging system as claimed in claim 4, wherein the data acquisition unit comprises:
a charger connection checking unit configured to determine whether or not the charger is connected to the application;
a connection time counting unit configured to count a connection time to determine whether or not a connection state continues for a reference time when the charger connection checking unit determines that the charger is connected;
a data reception unit configured to receive data from a data transmission unit of the BMS of the application when the connection time counting unit determines that the connection of the charger continues for the reference time; and
a data consistency determination unit configured to determine and verify consistency of the received data.

8. The secondary battery charging system as claimed in claim 1, wherein the BMS comprises:
a battery state information acquisition unit configured to acquire battery state information;
an event information acquisition unit configured to acquire event-related information of at least one of the battery and the application; and
a data transmission unit configured to transmit the acquired battery state information and the event-related information.

9. The secondary battery charging system as claimed in claim 1, wherein the BMS comprises:
a temperature sensor position information collection unit configured to collect a position of a sensor configured to measure a temperature of the battery;
an event occurrence detection unit configured to detect occurrence of an event in at least one of the battery and the application; and
an event occurrence notification unit configured to transmit an event occurrence notification signal to the charger when the event occurrence detection unit detects the occurrence of the event.

10. The secondary battery charging system as claimed in claim 9, wherein the event occurrence notification unit is configured to transmit the event occurrence notification signal with higher priority than the data that will be transmitted to the charger.

11. A data backup method performed in a secondary battery charging system, the secondary battery charging system comprising: an application comprising a battery and a battery management system (BMS); and a charger configured to supply charging power to the battery of the application and to communicate with the application, the data backup method comprising:
acquiring, by the BMS, battery state information;
acquiring, by the BMS, event-related information in at least one of the battery and the application; and
transmitting the acquired battery state information and the event-related information to the charger.

12. The data backup method as claimed in claim 11, further comprising:
determining, by the charger, whether or not the charger is connected to the application;
when it is determined that the charger is connected, receiving data from a data transmission unit of the BMS of the application; and
determining and verifying consistency of the received data.

13. The data backup method as claimed in claim 11, further comprising:
determining whether or not the charger is connected to the application;
when it is determined that the charger is connected, counting a connection time;
when it is determined that the connection of the charger continues for a reference time, receiving data from a data transmission unit of the BMS of the application; and
determining and verifying consistency of the received data.

14. The data backup method as claimed in claim 11, wherein the secondary battery charging system further comprises a data backup system configured to receive data from the charger and store the received data, and
wherein the data backup method further comprises:
determining, by the data backup system, whether or not the charger is connected to the application;
when it is determined that the charger is connected, receiving data from a data transmission unit of the BMS of the application; and
determining and verifying consistency of the received data.

15. The data backup method as claimed in claim 11, wherein the secondary battery charging system further comprises a data backup system configured to receive data from the charger and store the received data, and
wherein the data backup method further comprises:
determining, by the data backup system, whether or not the charger is connected to the application;
when it is determined that the charger is connected, counting a connection time;
when it is determined that the connection of the charger continues for a reference time, receiving data from a data transmission unit of the BMS of the application; and
determining and verifying consistency of the received data.

16. The data backup method as claimed in claim 11, further comprising:
collecting, by the BMS, a position of a sensor configured to measure a temperature of the battery;
detecting occurrence of an event in at least one of the battery and the application; and
when the occurrence of the event is detected, transmitting an event occurrence notification signal to the charger.

17. The data backup method as claimed in claim 16, wherein the event occurrence notification signal is transmitted with higher priority than data that will be transmitted to the charger.

18. The data backup method as claimed in claim 16, wherein the detecting of the occurrence of the event comprises detecting the occurrence of the event when the acquired battery state information matches at least one of a tendency and a threshold of battery state information stored for each type of an event.

19. The data backup method as claimed in claim 16, wherein the detecting of the occurrence of the event is performed by using an artificial intelligence technique through the acquired battery state information.

20. The data backup method as claimed in claim 16, wherein the event occurrence notification signal comprises the acquired battery state information, event information, and temperature sensor position information of the battery or the application in which the event has occurred.
